(19) United States
(12) Patent Application Publication
(10) Pub. No.: US 2024/0332023 A1
(43) Pub. Date: Oct. 3, 2024

(54) METHOD OF MAKING SILICIDE IN HIGH-ASPECT RATIO STRUCTURES BY HYBRID PROCESSES

(71) Applicant: Applied Materials, Inc., Santa Clara, CA (US)

(72) Inventors: Ying-Bing JIANG, Woodland, CA (US); In Seok HWANG, Pleassanton, CA (US); Zhijun CHEN, San Jose, CA (US); Avgerinos V. GELATOS, Scotts Valley, CA (US); Joung Joo LEE, San Jose, CA (US); Xianmin TANG, San Jose, CA (US); Fredrick FISHBURN, Aptos, CA (US); Le ZHANG, Santa Clara, CA (US); Wangee KIM, Santa Clara, CA (US); Mahendra PAKALA, Santa Clara, CA (US)

(21) Appl. No.: 18/621,828

(22) Filed: Mar. 29, 2024

Related U.S. Application Data
(60) Provisional application No. 63/601,887, filed on Nov. 22, 2023.
(60) Provisional application No. 63/455,961, filed on Mar. 30, 2023.

(51) Int. Cl. H01L 21/285; C23C 16/24; C23C 16/34; C23C 16/40; C23C 16/455

(52) U.S. Cl. CPC H01L 21/28518; C23C 16/24; C23C 16/345; C23C 16/401; C23C 16/45557

(57) ABSTRACT

The present disclosure relates to a method of selectively forming a silicide in high-aspect ratio structures by use of a multistep deposition process. A first precursor gas is delivered to a surface disposed within a processing region of a process chamber maintained at a first process pressure, where the substrate is maintained at a first temperature for a first period of time. A purge gas is delivered to for a second period of time after the first period of time has elapsed. A second precursor gas is delivered to the surface of the substrate. The second precursor being maintained at a second process pressure while the substrate is maintained at a second temperature for a third period of time. The purge gas is delivered to the processing region for a fourth period of time after the third period of time has elapsed.

### CROSS-REFERENCE TO RELATED APPLICATIONS

This application claims priority to U.S. Provisional Patent Application No. 63/455,961, filed Mar. 30, 2023, and U.S. Provisional Patent Application No. 63/601,887, filed on Nov. 22, 2023, each of which are incorporated herein by reference in their entireties.

### BACKGROUND

### Field

Embodiments described herein generally relate to semiconductor device fabrication, and more particularly, to systems and methods of forming bit lines in three-dimensional dynamic random-access memory devices.

### Description of the Related Art

Three-dimensional (3D) dynamic random-access memory (DRAM) devices pose challenges in manufacturability due to their 3D designs and small sizes. Individual memory cells, each of which includes a field-effect transistor (FET) device, need to be connected to a bit line at the source/drain regions of the FET device. Fabrication of such bit lines typically requires line-of-sight processing and multiple process steps including a high-aspect-ratio (HAR) etching process to form slots for bit lines. For example, a 3D DRAM device may include alternating layers of silicon-based layers (P), oxide (O), nitride (N). In some configurations of the 3D DRAM structure the silicon-based layers are selectively recessed, while in some other configurations the silicon-based layers are exposed in the vertical bit- line openings. In a 3D memory structure, such as 3D DRAM, silicide contacts are needed to be formed on the exposed portions of the silicon-based layers formed on the sidewalls of the deep HAR holes or deep HAR trenches. Conventional deposition techniques typically form the silicide layers at one specific and optimized dep-condition, but the species concentration gradient developed during transport in the deep holes/trenches will inherently cause non-uniformity of deposition. This conventional approach for forming the silicide layers in the vertical bit line features results in variations in the silicide layer properties which, among other things, leads to variations in the electrical characteristics of the 3D DRAM device.

Thus, there is a need for systems and methods that can fabricate vertical bit lines in a 3D DRAM device that solves the problems described herein.

### SUMMARY

The present disclosure generally provides methods of making silicide in high-aspect ratio structures by hybrid processes. The methods include depositing a layer in a high aspect ratio feature formed in a device layer stack. The device layer stack includes a repeating stack of ONPN layers. The methods include delivering a first precursor gas to a surface of a substrate disposed within a processing region of a process chamber, in which the processing region is maintained at a first process pressure while the substrate is maintained at a first temperature for a first period of time. A purge gas is delivered to the processing region for a second period of time, in which the purge gas is provided after the first period of time has elapsed. A second precursor gas is delivered to the surface of the substrate disposed within the processing region of the process chamber, in which the second processing region is maintained at a second process pressure while the substrate is maintained at a second temperature for a third period of time. The purge gas is delivered to the processing region for a fourth period of time, in which the purge gas is provided after the third period of time has elapsed.

The present disclosure also includes a method of delivering the first precursor gas for the first period of time and delivering the purge gas to the processing region for the second period of time being cyclically repeated two or more times before delivering the second precursor gas to the surface of the substrate for the third period of time. The present disclosure also includes a method that includes, after delivering the first precursor gas to the surface of the substrate for the first period of time, delivering the second precursor gas for the third period of time and delivering the purge gas to the processing region for the fourth period of time two or more times before delivering the first precursor gas to the surface of the substrate for the first period of time a second time.

The present disclosure also generally provides methods of making silicide in high-aspect ratio structures by hybrid processes. The methods include depositing a layer in a high aspect ratio feature formed in a device layer stack. The device layer stack includes a repeating stack of ONPN layers. The methods include delivering a first precursor gas to a surface of a substrate disposed within a processing region of a process chamber, in which the processing region is maintained at a first process pressure while the substrate is maintained at a first temperature for a first period of time. A purge gas is delivered to the processing region for a second period of time, in which the purge gas is provided after the first period of time has elapsed. The first precursor gas is delivered to the surface of the substrate, in which the processing region is maintained at a second process pressure while the substrate is maintained at a second temperature for a third period of time. The purge gas is delivered to the processing region for a fourth period of time, in which the purge gas is provided after the third period of time has elapsed. A second precursor gas is delivered to the surface of the substrate disposed within the processing region of the process chamber, in which the second processing region is maintained at a third process pressure while the substrate is maintained at a third temperature for a fifth period of time. The purge gas is delivered to the processing region for a sixth period of time, in which the purge gas is provided after the fifth period of time has elapsed.

The present disclosure also generally provides methods of making silicide in high-aspect ratio structures by hybrid processes. The methods include depositing a layer in a high aspect ratio feature formed in a device layer stack. The device layer stack includes a repeating stack of ONPN layers. The methods include delivering a first precursor gas to a surface of a substrate disposed within a processing region of a process chamber, in which the processing region is maintained at a first process pressure while the substrate is maintained at a first temperature for a first period of time. A purge gas is delivered to the processing region for a second period of time, in which the purge gas is provided after the first period of time has elapsed. A second precursor gas is delivered to the surface of the substrate, in which the processing region is maintained at a second process pressure while the substrate is maintained at a second temperature for a third period of time. The purge gas is delivered to the processing region for a fourth period of time, in which the purge gas is provided after the third period of time has elapsed. The second precursor gas is delivered to the surface of the substrate disposed within the processing region of the process chamber, in which the second processing region is maintained at a third process pressure while the substrate is maintained at a third temperature for a fifth period of time. The purge gas is delivered to the processing region for a sixth period of time, in which the purge gas is provided after the fifth period of time has elapsed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A-1C illustrate a substrate undergoing a selective deposition process, according to embodiments of the disclosure. FIG. 1A illustrates a substrate prior to performing the selective deposition process. FIG. 1B illustrates a substrate during or after performing a clean process. FIG. 1C illustrates a substrate while performing a selective deposition process.

FIG. 2 illustrates a first iterative selective deposition process, according to embodiments of the disclosure.

FIG. 3 illustrates a second iterative selective deposition process, according to embodiments of the disclosure.

FIG. 4 illustrates a third iterative selective deposition process, according to embodiments of the disclosure.

FIG. 5 illustrates a fourth iterative selective deposition process, according to embodiments of the disclosure.

FIG. 6 illustrates a fifth iterative selective deposition process, according to embodiments of the disclosure.

FIG. 7 illustrates a sixth iterative selective deposition process, according to embodiments of the disclosure.

FIG. 8 illustrates a seventh iterative selective deposition process, according to embodiments of the disclosure.

FIG. 9 illustrates an eighth iterative selective deposition process, according to embodiments of the disclosure.

FIG. 10 illustrates a ninth iterative selective deposition process, according to embodiments of the disclosure.

FIG. 11 illustrates a tenth iterative selective deposition process, according to embodiments of the disclosure.

FIG. 12 illustrates an eleventh iterative selective deposition process, according to embodiments of the disclosure.

FIG. 13 illustrates a twelfth iterative selective deposition process, according to embodiments of the disclosure.

FIG. 14 illustrates a thirteenth iterative selective deposition process, according to embodiments of the disclosure.

FIG. 15 illustrates a fourteenth iterative selective deposition process, according to embodiments of the disclosure.

FIG. 16 illustrates a fifteenth iterative selective deposition process, according to embodiments of the disclosure.

FIG. 17 illustrates a sixteenth iterative selective deposition process, according to embodiments of the disclosure.

FIG. 18 illustrates an example of a two-process step containing processing sequence, according to embodiments of the disclosure.

FIG. 19 illustrates a three-process step containing first selective deposition process, second selective deposition process, and third selective deposition process, according to embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a method of selectively forming a silicide in high-aspect ratio structures by use of a multistep deposition process, which is often referred to herein as a hybrid deposition process.

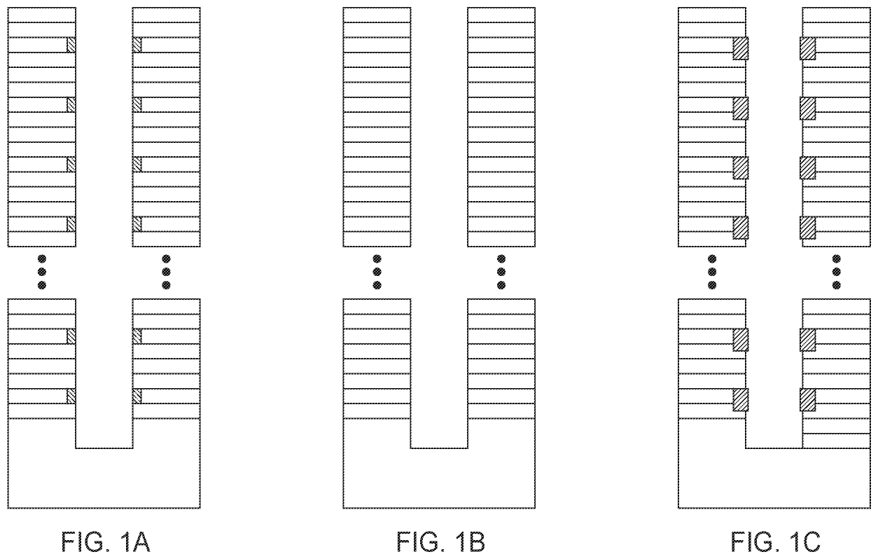

The method includes receiving a wafer having a plurality of native oxide layers covering a silicon-based layer of a 3D DRAM structure, as shown in FIG. 1A. The wafer includes a plurality of vertical channels extending from a top side of the wafer to a bottom side of the wafer. The vertical channels are formed in a stack of repeating ONPN layers, that include sequential repeating stack of an oxide layer (e.g., SiOₓ), a first nitride layer (e.g., silicon nitride (SiₓN_{y})), a silicon layer (e.g., polysilicon, a-silicon, c-silicon), and a second nitride layer (e.g., silicon nitride (SiₓN_{y})). The channels may have a depth of about 2 μm to about 6 μm, e.g., about 2 μm, about 3 μm, about 4 μm, about 5 μm, about 6 μm, or the like. The channels may include an aspect ratio of about 1:8 to about 1:160, e.g., about 1:8, about 1:10, about 1:50, about 1:100, about 1:150, about 1:160; or the like.

The method includes cleaning the wafer to remove a native oxide formed on the silicon containing layer, either by wet etch, e.g., d-HF solution, or dry etch (NH₃—HF), as shown in FIG. 1B.

The method includes performing a first selective deposition process, as shown in FIG. 1C. The deposition process is performed in a processing region of a deposition chamber. The first selective deposition process includes dosing the cleaned wafer with a precursor gas that includes a metal species, e.g., molybdenum chloride, titanium chloride, or the like, as shown in FIG. 1C. The metal species may include molybdenum pentachloride. The metal species may include titanium pentachloride. The dose is applied for less than about 3 seconds. For example, and without limitation, the dose may be applied for less than 2 seconds. As a further non-limiting example, the dose may be applied for about 2 seconds to about 3 seconds, e.g., about 2.1 seconds, about 2.2 seconds, about 2.3 seconds, about 2.4 seconds, about 2.5 seconds, about 2.6 seconds, about 2.7 seconds, about 2.8 seconds, about 2.9 seconds, about 3.0 seconds, or the like.

A purge gas (e.g., inert gas) is then provided to the wafer that is disposed within the deposition chamber to remove one or more of the chlorinated species. The purge gas is an inert gas capable of removing the chlorinated species, e.g., argon, nitrogen, helium, or the like. The purge gas is applied for about 1x the dose time to about 4x the dose time. For example, the purge time may be about 4.5 seconds when the dose time is about 3 seconds. As a further non-limiting example, the purge time may be about 1.5 seconds when the dose time is about 3.5 seconds.

The first selective deposition process includes a first temperature. Without wishing to be bound by theory the temperature of the wafer during processing may influence the location of the deposition process within the vertical channels formed in the multilayer stack. For example, a high temperature, e.g., greater than about 380° C., may provide better efficiency of depositing the metal species towards a top section of the vertical channels, whereas a low temperature, e.g., less than about 350° C., may provide better efficiency of depositing the metal species towards a bottom section of the vertical channels. The first temperature is a high temperature, in which the first temperature is greater than about greater than about 380° C.

The first selective deposition process includes a first pressure. Without wishing to be bound by theory the pressure of the chamber may influence the location of the deposition process within the vertical channels. For example, a pressure, e.g., greater than about 10 Torr, may provide better efficiency of depositing the metal species, e.g., molybdenum chloride, titanium chloride, or a combination thereof towards a top section of the vertical channels, whereas a low pressure, e.g., less than about 10 Torr, may provide better efficiency of depositing the metal species towards a bottom section of the vertical channels. The first pressure is a high pressure, in which the first pressure is about 10 Torr to about 760 Torr, e.g., about 10 Torr to about 700 Torr, about 10 Torr to about 500 Torr, about 10 Torr to about 300 Torr, or about 10 Torr to about 100 Torr.

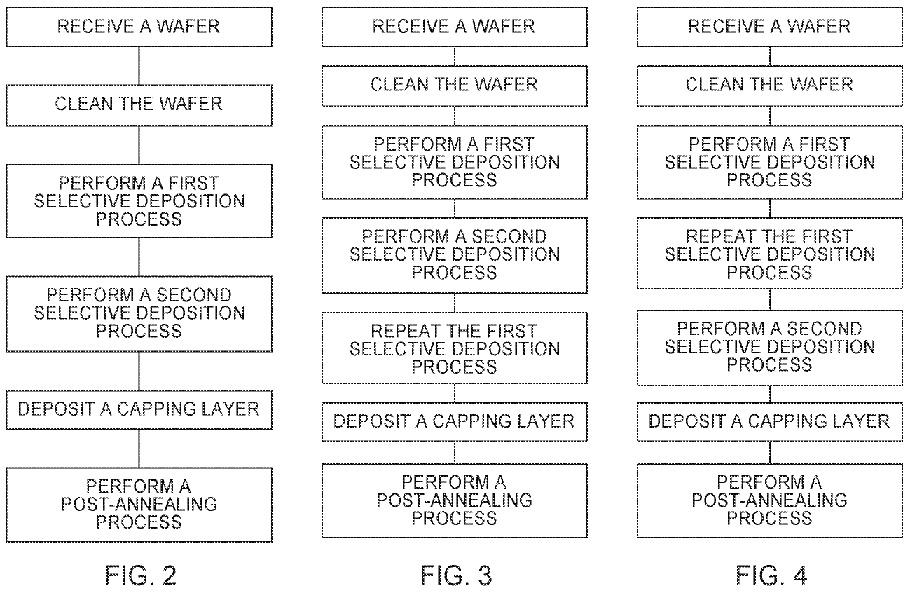

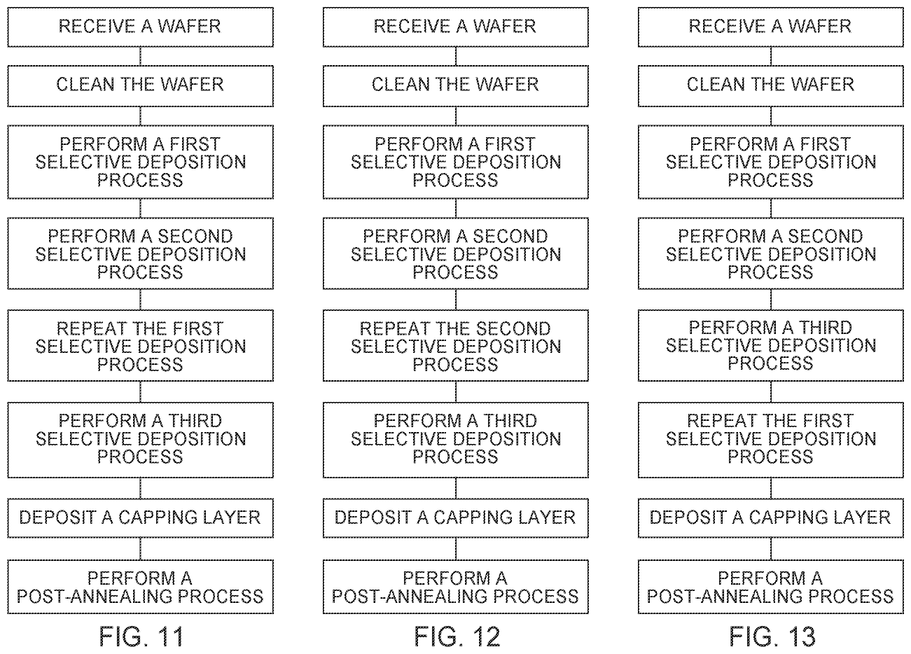

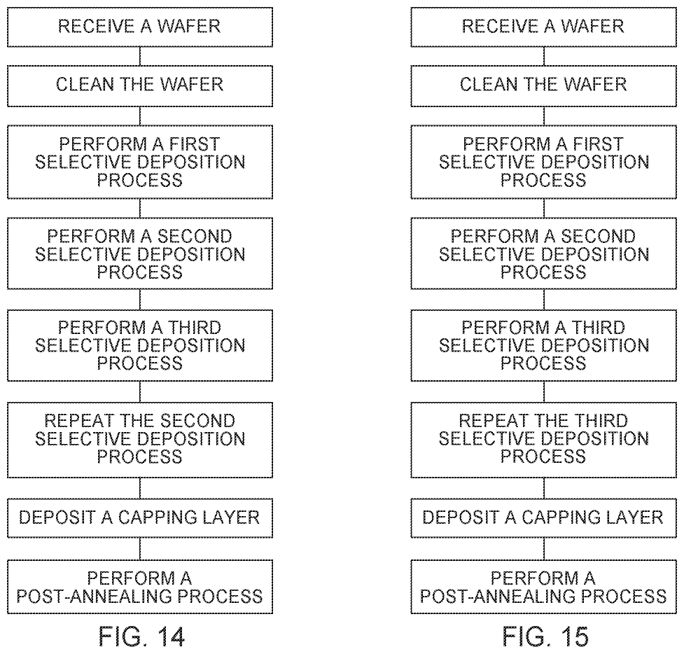

The method includes performing a second selective deposition process, as shown in FIGS. 2-17. The second selective deposition process includes dosing the cleaned wafer with a precursor gas that includes a metal species, e.g., molybdenum chloride, titanium chloride, or a combination thereof, as described herein. A purge gas is applied to remove the chlorinated species from wafer, as described above. For example, the second selective deposition process may include a dose time of about 3 seconds, and a purge time of about 7 seconds.

The second selective deposition process includes a second temperature. In some embodiments, the second temperature is a low temperature, in which the second temperature is about 300° C. to about 350° C., e.g., about 300° C. to about 350° C., about 310° C. to about 350° C., or about 335° C. to about 350° C. The second selective deposition process includes a second pressure. In some embodiments, the second pressure is a low pressure, in which the second pressure is about 0.001 Torr about 10 Torr, e.g., 0.001 Torr to about 8 Torr, about 0.01 Torr to about 5 Torr, about 0.1 Torr to about 3 Torr, or about 0.5 Torr to about 1 Torr.

The method may include performing a third selective deposition process, as shown in FIGS. 2-17. The third selective deposition process includes dosing the cleaned wafer with a metal species, e.g., molybdenum chloride, titanium chloride, a combination thereof, as described herein. A purge gas is applied to remove the chlorinated species from wafer, as described above.

The third selective deposition process include a third temperature. The third temperature is a medium temperature, in which the third temperature is between about 350° C. and 380° C., e.g., about 350°° C. to about 370° C., about 355° C. to about 370° C., or about 360° C. to about 370° C. The third selective deposition process includes a third pressure. The third pressure is a medium pressure, in which the third pressure is between about 10 Torr to about 400 Torr, e.g., about 10 Torr to about 400 Torr, about 12 Torr to about 300 Torr, about 14 Torr to about 200 Torr, or about 14 Torr to about 100 Torr.

In an embodiment, the method includes an iterative process that repeats one or more of the first selective deposition process and the second selective deposition process, as shown in FIGS. 2-7. For example, and without limitation, an iterative process may include performing a first selective deposition process, a second selective deposition process, and repeating the first selective deposition process. As a further non-limiting example, an iterative process may include performing a first selective deposition process, a second selective deposition process, and repeating the second selective deposition process. As a further non- limiting example, an iterative process may include performing a first selective deposition process, a second selective deposition process, and repeating the first selective deposition process and the second selective deposition process at least one more time. As a further non-limiting example, an iterative process may include performing a first selective deposition process, repeating the first selective deposition process, and performing a second selective deposition process.

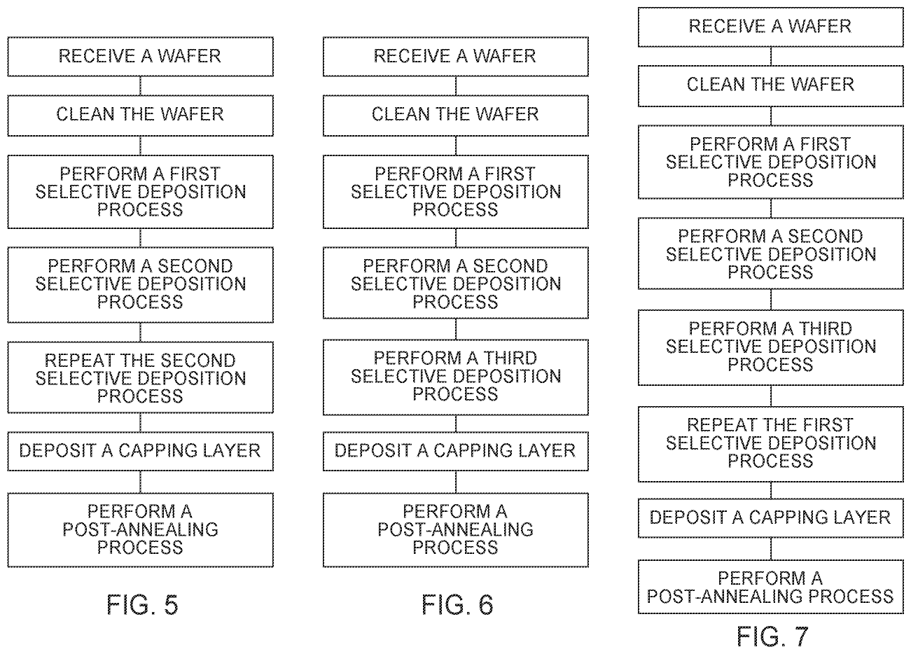

In an embodiment, the method includes an iterative process that repeats one or more of the first selective deposition process, the second selective deposition process, or the third selective deposition process, as shown in FIGS. 5-6. For example, and without limitation, an iterative process may include performing a first selective deposition process, a second selective deposition process, a third selective deposition process, and repeating the first selective deposition process. As a further non-limiting example, an iterative process may include performing a first selective deposition process, a second selective deposition process, a third selective deposition process, and repeating the second selective deposition process. As a further non-limiting example, an iterative process may include performing a first selective deposition process, a second selective deposition process, a third selective deposition process, and repeating the third selective deposition process.

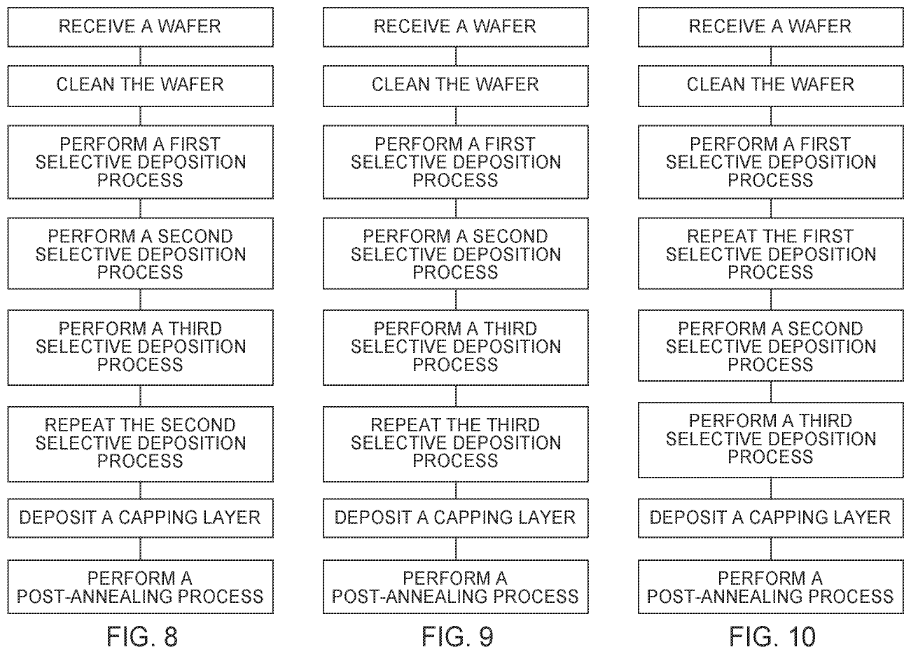

The repetition may be performed after the first selective deposition process, second selective deposition process, third selective deposition process, or in between each of the processes, as shown in FIGS. 8-15. For example, and without limitation, the iterative process may include performing a first selective deposition process, repeating the first selective deposition process, and performing a second selective deposition process followed by a third selective deposition process. As a further non-limiting example, the iterative process may include performing a first selective deposition process and a second selective deposition process, repeating the first selective deposition process, and performing a third selective deposition process. As a further non-limiting example, the iterative process may include performing a first selective deposition process and a second selective deposition process, repeating the second selective deposition process, and performing a third selective deposition process. As a further non-limiting example, the iterative process may include performing a first selective deposition process, a second selective deposition process, a third selective deposition process, and repeating the first selective deposition process. As a further non-limiting example, the iterative process may include performing a first selective deposition process, a second selective deposition process, a third selective deposition process, and repeating the second selective deposition process. As a further non-limiting example, the iterative process may include performing a first selective deposition process, a second selective deposition process, a third selective deposition process, and repeating the third selective deposition process.

In some embodiments, one or more process variables may differ from a process variable within the other process sequences. For example, the first selective deposition process (A), may include dosing a first metal species, e.g., molybdenum chloride, titanium chloride, or a combination thereof, at a pressure that is about 10 Torr to about 760 Torr, e.g., about 10 Torr to about 700 Torr, about 10 Torr to about 500 Torr, about 10 Torr to about 300 Torr, or about 10 Torr to about 100 Torr, a temperature of about 360° C. to about 400° C., e.g., about 360° C. to about 390° C., about 370° C. to about 390° C., or about 375° C. to about 395° C., purging the metal species with an inert gas using a purge time of about 0.1 seconds to about 2 seconds, e.g., about 0.1 seconds to about 1.9 seconds, about 0.5 seconds to about 1.8 seconds, or about 1 second to about 1.5 seconds, performing a second deposition process (B) by dosing a second metal species e.g., molybdenum chloride, titanium chloride, or a combination thereof, at a pressure of about 0.001 Torr about 50 Torr, e.g., 0.001 Torr to about 48 Torr, about 0.01 Torr to about 45 Torr, about 0.1 Torr to about 33 Torr, or about 0.5 Torr to about 20 Torr, and a temperature of about 300° C. to about 350° C., e.g., about 300° C. to about 350° C., about 310° C. to about 350° C., or about 335° C. to about 350° C., and purging the second metal species with an inert gas using a purge time of about 2.1 seconds to about 30 seconds, e.g., about 2.1 seconds to about 28 seconds, about 3 seconds to about 25 seconds, about 4 seconds to about 20 seconds, or about 5 seconds to about 15 seconds. In an embodiment, the third selective deposition process (C) may include similar parameters to that of A, and/or the third selective deposition process may include different process parameters than either A or B.

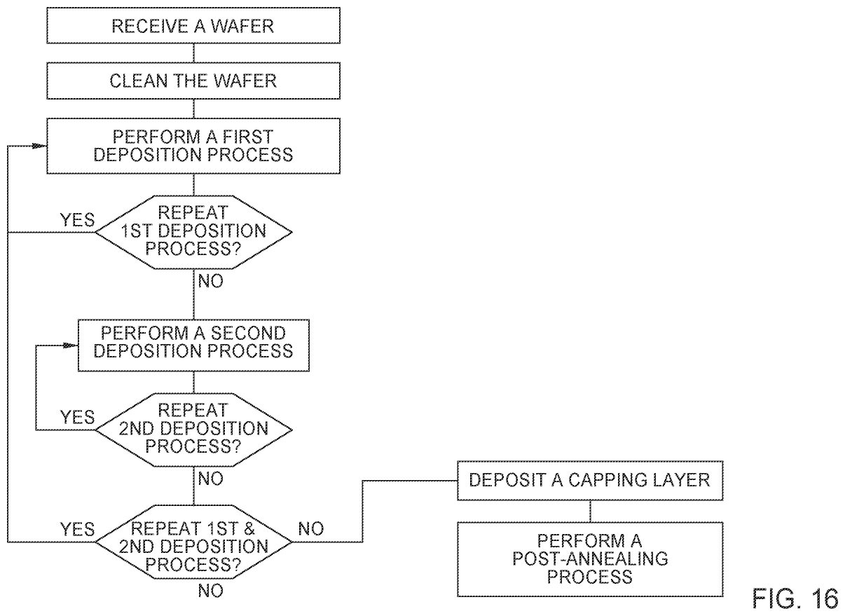

FIG. 16 illustrates an example of a two-process step containing processing sequence in which one or more first selective deposition processes (P1) and one or more second selective deposition processes (P2) can each be individually repeated zero to N times, where N is an integer greater than zero (e.g., 1, 2, 5, 10, 100, etc.), or interleaved in any desired sequence to form a deposited layer within a feature. Each of the selective deposition processes in the process sequence will include at least on process variable that is different from a process variable within the other process sequences. In one example, the process variable is selected from a process pressure, temperature, deposition time, and ratio of deposition-to-purge time. In one example, the processing sequence could include a sequence P1-P2-P1-P2 . . . P1-P2. In some embodiments, each selective deposition process (e.g., P1 or P2) can be performed cyclically two or more times before another selective deposition process is performed. In one example, the processing sequence could include a sequence P1-P1-P2-P1-P1-P2. In yet another example, the processing sequence could include a sequence P1-P2-P2-P1-P2 . . . P1-P2-P2-P1-P2.

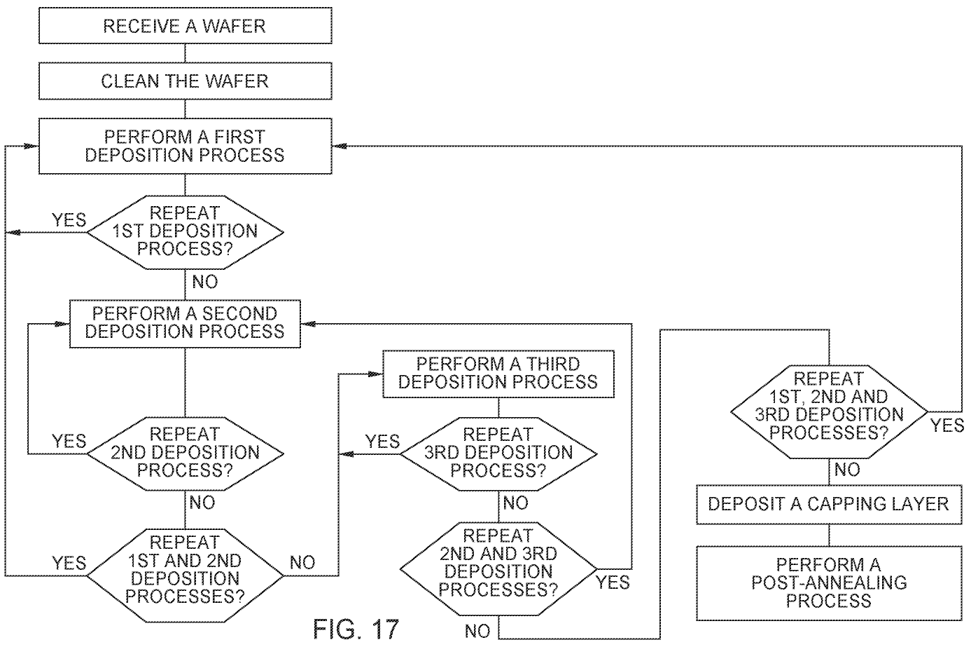

FIG. 17 illustrates an example of a three-process step containing processing sequence in which one or more first selective deposition processes (P1), one or more second selective deposition processes (P2) and one or more third selective deposition processes (P3) can each be individually repeated zero to N times, where N is an integer greater than zero (e.g., 1, 2, 5, 10, 100, etc.), or interleaved in any desired sequence to form a deposited layer within a feature. In one example, the processing sequence could include a sequence P1-P2-P3-P1-P2-P3 . . . P1-P2-P3.

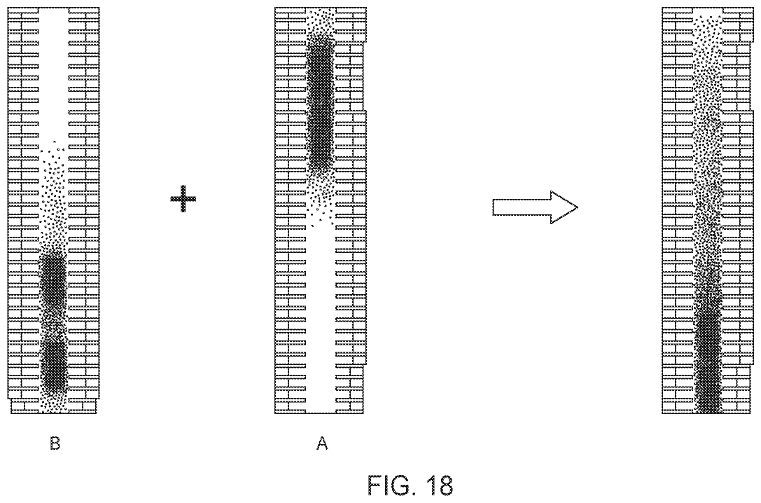

FIG. 18 illustrates an example of a two-process step containing processing sequence in which one or more first selective deposition processes (A) and one or more second selective deposition processes (B) can each be individually repeated zero to N times, where N is an integer greater than zero (e.g., 1, 2, 5, 10, 100, etc.), or interleaved in any desired sequence to form a deposited layer within a feature. Each of the selective deposition processes in the process sequence will include at least on process variable that is different from a process variable within the other process sequences. In one example, the process variable is selected from a process pressure, temperature, deposition time, and ratio of deposition-to-purge time. In one example, the processing sequence could include a sequence BA-BA-BA . . . BA. In another example, the processing sequence could include a sequence BBA-BBA . . . BBA. In yet another example, the processing sequence could include a third selective deposition process (C), where the processing sequence could include a sequence BAC-BAC-BAC . . . BAC.

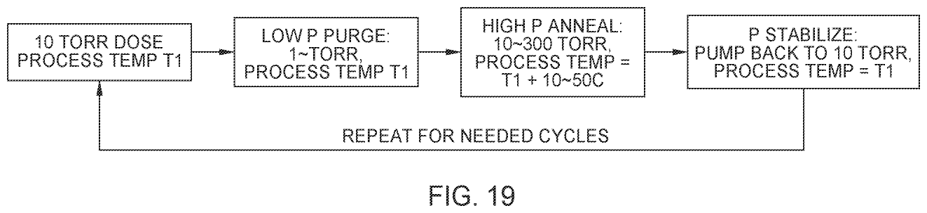

FIG. 19 illustrates a three-process step sequence containing a first selective deposition process (P1) too deposit a first metal species, e.g., molybdenum chloride, titanium chloride, or a combination thereof. The first selective deposition process includes a first temperature (T1) of about 360° C. to about 400° C., e.g., about 360°° C. to about 390° C., about 370° C. to about 390° C., or about 375° C. to about 395° C., and a first pressure of about 10 Torr to about 760 Torr, e.g., about 10 Torr to about 700 Torr, about 10 Torr to about 500 Torr, about 10 Torr to about 300 Torr, or about 10 Torr to about 20 Torr, a temperature of about 360° C. to about 400° C. The three-process step sequence includes a second selective deposition process (P2) to deposit a second metal species, e.g., molybdenum chloride, titanium chloride, or a combination thereof. The second selective deposition process includes the first temperature (T1) and a second pressure of about 1 Torr to about 6 Torr, e.g., about 1 Torr to about 5 Torr, about 2 Torr to about 4 Torr, or about 3 Torr to about 4 Torr. The three-process step sequence includes a third selective deposition process (P3), to deposit a third metal species, e.g., molybdenum chloride, titanium chloride, or a combination thereof, the third metal species being the same or different from the first metal species or the second metal species. The third selective deposition process includes a second temperature that is about 10° C. to about 50°° C. greater than T1, e.g., about 370° C. to about 450° C., e.g., about 370°° C. to about 440° C., about 380° C. to about 420° C., or about 390°° C. to about 410° C. The third selective deposition process includes a third pressure of about 10 Torr to about 300 Torr, e.g., about 10 Torr to about 280 Torr, about 10 Torr to about 200 Torr, about 10 Torr to about 100 Torr, or about 10 Torr to about 50 Torr. The three-process step sequence may then proceed to the first selective deposition process, e.g., a pressure of about 10 Torr to about 20 Torr and a temperature of about 360° C. to about 400° C., where the three-process step sequence may repeat the process sequence multiple times.

While the foregoing is directed to embodiments of the present disclosure, other and further embodiments of the disclosure may be devised without departing from the basic scope thereof, and the scope thereof is determined by the claims that follow.

What is claimed is:

1. A method of selectively depositing a layer in a high aspect ratio feature formed in a device layer stack, wherein the device layer stack comprises a repeating stack of ONPN layers, the method comprising:
delivering a first precursor gas to a surface of a substrate disposed within a processing region of a process chamber, wherein delivering the first precursor gas comprises maintaining the processing region at a first process pressure while the substrate is maintained at a first temperature for a first period of time;
delivering a purge gas to the processing region for a second period of time, wherein delivering the purge gas is provided after the first period of time has elapsed;
delivering a second precursor gas to the surface of the substrate disposed within the processing region of the process chamber, wherein delivering the second precursor gas comprises maintaining the processing region at a second process pressure while the substrate is maintained at a second temperature for a third period of time; and
delivering the purge gas to the processing region for a fourth period of time, wherein delivering the purge gas is provided after the third period of time has elapsed.

2. The method of claim 1, wherein the first pressure is higher than the second pressure.

3. The method of claim 2, wherein the first temperature is higher than the second temperature.

4. The method of claim 1, wherein the second period of time is either greater than or less than the fourth period of time.

5. The method of claim 1, wherein the first precursor gas and the second precursor gas comprise molybdenum or titanium.

6. The method of claim 5, wherein the first precursor gas and the second precursor gas comprise titanium chloride.

7. The method of claim 5, wherein the first precursor gas and the second precursor gas comprise molybdenum chloride.

8. The method of claim 1, wherein a first ratio of first period of time to the second period of time is greater than a second ratio of the third period of time to the fourth period of time.

9. The method of claim 1, wherein a first ratio of the first period of time to the second period of time is less than a second ratio of the third period of time to the fourth period of time.

10. The method of claim 1, wherein delivering the first precursor gas for the first period of time and delivering the purge gas to the processing region for the second period of time is cyclically repeated two or more times before delivering the second precursor gas to the surface of the substrate for the third period of time.

11. The method of claim 1, wherein the P layer in the ONPN stack is a silicon containing layer.

12. The method of claim 11, wherein the O layer and the N layers in the ONPN stack are an oxide layer and nitride layers, respectively.

13. A method of selectively depositing a layer in a high aspect ratio feature formed in a device layer stack, wherein the device layer stack comprises a repeating stack of ONPN layers, the method comprising:
delivering a first precursor gas to a surface of a substrate disposed within a processing region of a process chamber, wherein delivering the first precursor gas comprises maintaining the processing region at a first process pressure while the substrate is maintained at a first temperature for a first period of time;
delivering a purge gas to the processing region for a second period of time, wherein delivering the purge gas is provided after the first period of time has elapsed;
delivering the first precursor gas to the surface of the substrate, wherein delivering the first precursor gas comprises maintaining the processing region at a second process pressure while the substrate is maintained at a second temperature for a third period of time;
delivering the purge gas to the processing region for a fourth period of time, wherein delivering the purge gas is provided after the third period of time has elapsed;
delivering a second precursor gas to the surface of the substrate disposed within the processing region of the process chamber, wherein delivering the second precursor gas comprises maintaining the processing region at a third process pressure while the substrate is maintained at a third temperature for a fifth period of time; and
delivering the purge gas to the processing region for a sixth period of time, wherein delivering the purge gas is provided after the fifth period of time has elapsed.

14. The method of claim 13, wherein the first pressure is the same as the second pressure.

15. The method of claim 13, wherein the first temperature is the same as the second temperature.

16. The method of claim 13, wherein the first pressure and the second pressure are different from the third pressure.

17. The method of claim 13, wherein the first temperature and the second temperature are different from the third temperature.

18. The method of claim 13, wherein the first precursor gas and the second precursor gas comprise molybdenum or titanium.

19. The method of claim 13, wherein the first precursor gas and the second precursor gas comprise titanium chloride.

20. A method of selectively depositing a layer in a high aspect ratio feature formed in a device layer stack, wherein the device layer stack comprises a repeating stack of ONPN layers, the method comprising:
delivering a first precursor gas to a surface of a substrate disposed within a processing region of a process chamber, wherein delivering the first precursor gas comprises maintaining the processing region at a first process pressure while the substrate is maintained at a first temperature for a first period of time;
delivering a purge gas to the processing region for a second period of time, wherein delivering the purge gas is provided after the first period of time has elapsed;
delivering a second precursor gas to the surface of the substrate, wherein delivering the second precursor gas comprises maintaining the processing region at a second process pressure while the substrate is maintained at a second temperature for a third period of time;
delivering the purge gas to the processing region for a fourth period of time, wherein delivering the purge gas is provided after the third period of time has elapsed;
delivering the second precursor gas to the surface of the substrate disposed within the processing region of the process chamber, wherein delivering the second precursor gas comprises maintaining the processing region at a third process pressure while the substrate is maintained at a third temperature for a fifth period of time; and
delivering the purge gas to the processing region for a sixth period of time, wherein delivering the purge gas is provided after the fifth period of time has elapsed.
